(19) United States
(12) Patent Application Publication
(10) Pub. No.: US 2007/0023911 A1
(43) Pub. Date: Feb. 1, 2007

(54) ELECTRONIC DEVICE AND METHOD FOR MANUFACTURING THE ELECTRONIC DEVICE

(75) Inventor: Hidekazu MORIYAMA, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/457,866

(22) Filed: Jul. 17, 2006

(30) Foreign Application Priority Data
Jul. 27, 2005 (JP) 2005-216879

(51) Int. Cl. H01L 29/40; H01L 21/44

(52) U.S. Cl. 257/750; 257/766; 438/652; 438/656

(57) ABSTRACT

A method for manufacturing an electronic device in which a bonding pad composed of a foundation layer and a surface layer is formed on an Si layer or an Si-base insulation layer, comprises: forming, on the Si layer or Si-base insulation layer and by a droplet discharging method, the foundation layer using liquid material including one or more material(s) selected from Ni, Cr, and Mn or a compound thereof; and forming, on the foundation layer and by the droplet discharging method, the surface layer.

### BACKGROUND

1. Technical Field

The present invention relates to an electronic device such as a semiconductor integrated circuit or a semiconductor sensor and a manufacture method thereof.

2. Related Art

Recently, a method for manufacturing an electronic device has been known in which a minute conducting wire pattern or a circuit element for example is formed by the so-called droplet discharging method (see JP-A-2003-317945 for example). This technique is a technique in which a droplet discharging head as used in an ink discharge printer is used to discharge liquid material including particles of functional material onto a substrate to subsequently solidify (or form a film of) the liquid material by drying or the like. When compared with the photolithography method as a general patterning technique, the droplet discharging method has a simple process and provides a superior efficiency of the use of functional material and thus has attracted attention as a technique having improved productivity and environmental friendliness.

JP-A-2003-317945 is an example of related art.

The above-described droplet discharging method also can be applied to the formation of a bonding pad in an integrated circuit, a semiconductor sensor or the like. However, a film formed by the droplet discharging method consists of collection of particles of functional material and thus is generally inconvenient in that this film has poor contact with a surface layer of a substrate when compared with a film formed by the gas phase method for example. This has caused an inconvenience where, when a bonding pad is formed by Au having a preferred electric property and having a superior liquid material for example, the resultant bonding pad has an insufficient contact strength with a surface layer of a substrate, causing stress in wire bonding to peel the bonding pad from the surface layer of the substrate.

### SUMMARY

An advantage of the invention is to provide a method for manufacturing a highly reliable electronic device with a high productivity and an electronic device manufactured by this manufacture method.

According to an aspect of the invention, a method for manufacturing an electronic device in which a bonding pad composed of a foundation layer and a surface layer is formed on an Si layer or an Si-base insulation layer, includes: forming, on the Si layer or Si-base insulation layer and by a droplet discharging method, the foundation layer using liquid material including one or more material(s) selected from Ni, Cr, and Mn or a compound thereof, and forming, on the foundation layer and by the droplet discharging method, the surface layer.

According to the method for manufacturing an electronic device, a foundation layer having a preferred contact to the Si layer or an Si-base insulation layer is formed to subsequently form a surface layer on the foundation layer. Thus, a bonding pad having a superior peeling resistance can be formed. Furthermore, liquid material including Ni, Cr, and Mn or an oxide thereof used for the formation of the foundation layer is well matched with the droplet discharging method, thus reducing burdening factors in steps related to the droplet discharging. In this manner, a highly reliable electronic device can be manufactured with a high productivity.

It is preferable that, according to the method for manufacturing an electronic device of the invention, the surface layer is formed by liquid material including one or more particle(s) or a compound material selected from Au, Ag, and Cu.

According to the method for manufacturing an electronic device of the invention, the liquid material including Au, Ag, or Cu particles constituting the surface layer is well matched with the droplet discharging method and thus reduces burdening factors in steps related to the droplet discharging.

According to another aspect of the invention, an electronic device in which a bonding pad composed of a foundation layer and a surface layer is formed on an Si layer or an Si-base insulation layer, wherein: the foundation layer is formed on the Si layer or Si-base insulation layer by the droplet discharging method using liquid material including one or more material(s) selected from Ni, Cr, and Mn or a compound thereof; and the surface layer is formed on the foundation layer by the droplet discharging method.

According to the electronic device of the invention, the foundation layer having a preferred contact to the Si layer or an Si-base insulation layer improves the peeling resistance of the bonding pad. This suppresses the bonding pad from being peeled to cause disconnection. Furthermore, the liquid material including Ni, Cr, and Mn or the compound thereof for constituting the foundation layer is well matched with the droplet discharging method and thus reduces burdening factors in steps related to the droplet discharging. Thus, the electronic device of the invention is manufactured with a high productivity by the droplet discharging method while having reliability.

### BRIEF DESCRIPTION OF THE DRAWINGS

The invention will be described with reference to the accompanying drawings, wherein like numbers reference like elements.

FIG. 1 is a partially broken perspective view illustrating a main structure of an electronic device of First Embodiment.

FIG. 2 is a schematic view illustrating an example of the structure of a droplet discharging apparatus.

FIG. 3 is a flowchart illustrating steps for manufacturing an integrated circuit.

FIGS. 4A to 4D are a partially broken perspective view illustrating a process for manufacturing an integrated circuit.

FIG. 5 is a partially broken perspective view illustrating a main structure of an electronic device of Second Embodiment.

### DESCRIPTION OF EXEMPLARY EMBODIMENTS

Hereinafter, preferred embodiments of the invention will be described in detail with reference to the attached drawings.

Embodiments shown hereinbelow are preferred specific examples of the invention and thus have various technically preferable limitations. However, the scope of the invention is not limited to these embodiments so long as the following description specifically limits the invention. In the drawings referred to in the following description, the respective layers and members have scaled sizes different from the actual ones so that the layers and members can be recognized in the drawings.

### First Embodiment

(Structure of Electronic Device)

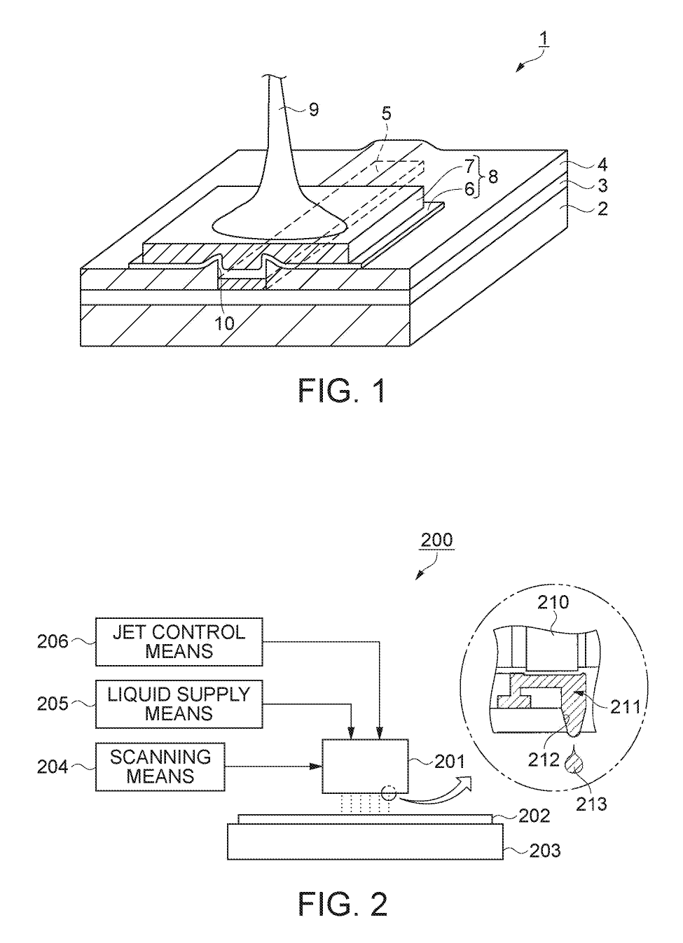

First, an electronic device according to First Embodiment will be described with reference to FIG. 1. FIG. 1 is a partially broken perspective view illustrating a main structure of the electronic device according to First Embodiment.

In FIG. 1, an integrated circuit 1 as an electronic device includes: a silicon substrate 2 including a semiconductor element (not shown); an insulation layer 3 that is formed on the silicon substrate 2 and that is made of BPSG (Boron-doped Phospho Silicate Glass) or the like; a conductive wiring 5 that is connected to the semiconductor element and that is made of Al or the like; and a covering layer 4 that covers the conductive wiring 5 and that is made of SiO₂, SiN or the like. The covering layer 4 has thereon a bonding pad 8 connected to the covering layer 4 via the conductive wiring 5 and a contact hole 10. The bonding pad 8 is connected to a lead frame (not shown) via a bonding wire 9.

The bonding pad 8 has a bilayer structure that includes a foundation layer 6 having a direct contact with the conductive wiring 5 and the covering layer 4; and a surface layer 7 formed on the foundation layer 6. The surface layer 7 is made of material that is selected in consideration of an electric property and a mechanical strength relating to the connection between the surface layer 7 and the bonding wire 9. In First Embodiment, the surface layer 7 is made of Au.

The foundation layer 6 has a role to improve the peeling resistance of the bonding pad 8 and is made of material that is selected in consideration of the contact with the covering layer 4 and the surface layer 7. The foundation layer 6 is made of Ni in First Embodiment. The foundation layer 6 also has another role to suppress the interdiffusion of Au and Si between the covering layer 4 and the surface layer 7. The foundation layer 6 preferably has a thickness of 20 nm to 400 nm. When the foundation layer 6 has an excessively thin thickness, the foundation layer 6 cannot sufficiently provide the function and, when the foundation layer 6 has an excessively thick thickness, an electric resistance will be increased.

The foundation layer 6 and the surface layer 7 constituting the bonding pad 8 are formed by the droplet discharging method. Details of the formation method will be described below.

(Droplet Discharging Apparatus and Liquid Material)

Next, a droplet discharging apparatus and liquid material used in the droplet discharging method will be described with reference to FIG. 2. FIG. 2 is a schematic view illustrating an example of the structure of a droplet discharging apparatus.

In FIG. 2, a droplet discharging apparatus 200 includes: a discharging head 201 on which a plurality of nozzles 212 are arranged on one surface; and a storage stand 203 that is opposed to the discharging head 201 and on which a substrate 202 is placed. The droplet discharging apparatus 200 also includes a scanning means 204 for moving (or scanning) the discharging head 201 in the longitudinal and lateral directions while keeping the distance to the substrate; a liquid material supply means 205 for supplying liquid material to the discharging head 201; and a control means 206 for controlling the discharge of the discharging head 201.

The discharging head 201 includes a plurality of branched minute flow channels an end of which has a pressure chamber (cavity) 211 and a nozzle 212. One surface of an outer part of the pressure chamber 211 can be deformed by a piezoelectric element 210. When a driving signal from the discharge control means 206 drives the piezoelectric element 210, the pressure chamber 211 is deformed, thereby allowing the nozzle 212 to discharge a droplet 213. A discharging technique includes, in addition to the electromechanical method as in this example, the so-called thermal method for converting an electrical signal to heat so that pressure is generated.

In the above-described structure, liquid material can be arranged on the substrate 202 with a desired pattern by controlling the discharge by the respective nozzles 212 in synchronization with the scanning of the discharging head 201. It is noted that the droplet discharging apparatus 200 also can be structured so that a plurality of types of liquid materials can be discharged by one scanning.

In this embodiment, Ni dispersion and Au dispersion are prepared as liquid material in which Ni particles and Au particles are dispersed in the liquid, respectively. The Ni dispersion is liquid material used for forming the foundation layer 6 (see FIG. 1). The Au dispersion is liquid material used for forming the surface layer 7 (see FIG. 1).

Dispersion medium constituting liquid material provides dispersion of the above-described particles and is not limited so long as the dispersion medium does not cause aggregation. Specifically, dispersion medium may be water, alcohol (e.g., methanol, ethanol), hydrocarbon compound (e.g., n-heptane, toluene), ether compound (e.g., ethylene glycol dimethyl ether), or polar compound (e.g., propylene carbonate, N-methyl 2-pyrrolidone). They may be individually used or two or more of them also may be used as a mixture.

Furthermore, liquid material is also adjusted so that the dispersion medium has appropriate vapor pressure, dispersoid concentration, surface tension, viscosity, gravity or the like in view of factors such as a discharging characteristic and a nozzle clogging characteristic of the droplet discharging apparatus 200, a dispersion stability, or a dynamic property and a drying rate on a substrate after a discharge operation. Thus, liquid material is added with an appropriate amount of surface-active agent, moisturizing agent, viscosity adjuster or the like. Liquid material also can be added with binder for improving the fixation after film formation.

Alternatively, Ni particles and Au particles also can be coated with organic matter (e.g., citric acid) in order to improve the dispersibility. These particles preferably have a particle size of about 1 to 100 nm. An excessively large particle size deteriorates the filling status of particles in the foundation layer 6 and the surface layer 7 (see FIG. 1), which worsens not only the contact and electric property but also the clogging characteristic of a nozzle of the droplet discharging apparatus 200. An excessively small particle size increases the volume ratio of coating agent to particles, which deteriorates the volume density of metal material to liquid material.

When the foundation layer 6 and the surface layer 7 (see FIG. 1) are formed by the droplet discharging method, material for the foundation layer 6 and the surface layer 7 should be selected in consideration of factors such as the easy control of the particle size and the stability to additive agent added to liquid material for example as described above. Based on the consideration for the factors, Ni is selected for the foundation layer 6 (see FIG. 1) and Au is selected for the surface layer 7 (see FIG. 1) in this embodiment so that the Ni dispersion and Au dispersion are well matched with the droplet discharging method.

(Manufacture Steps)

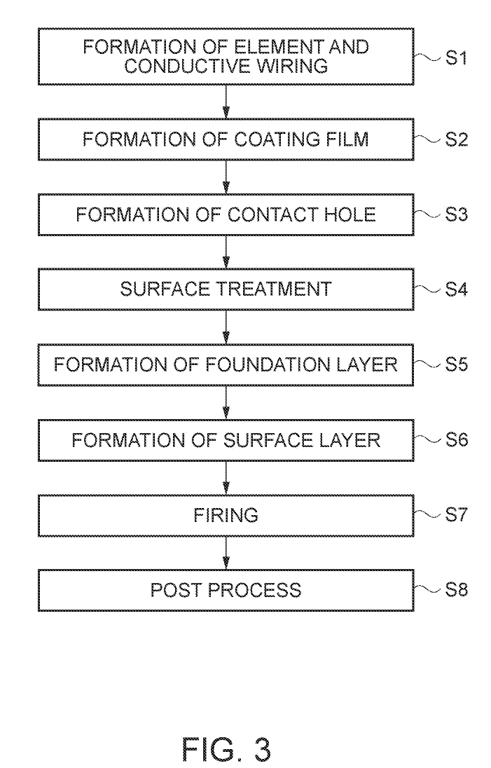

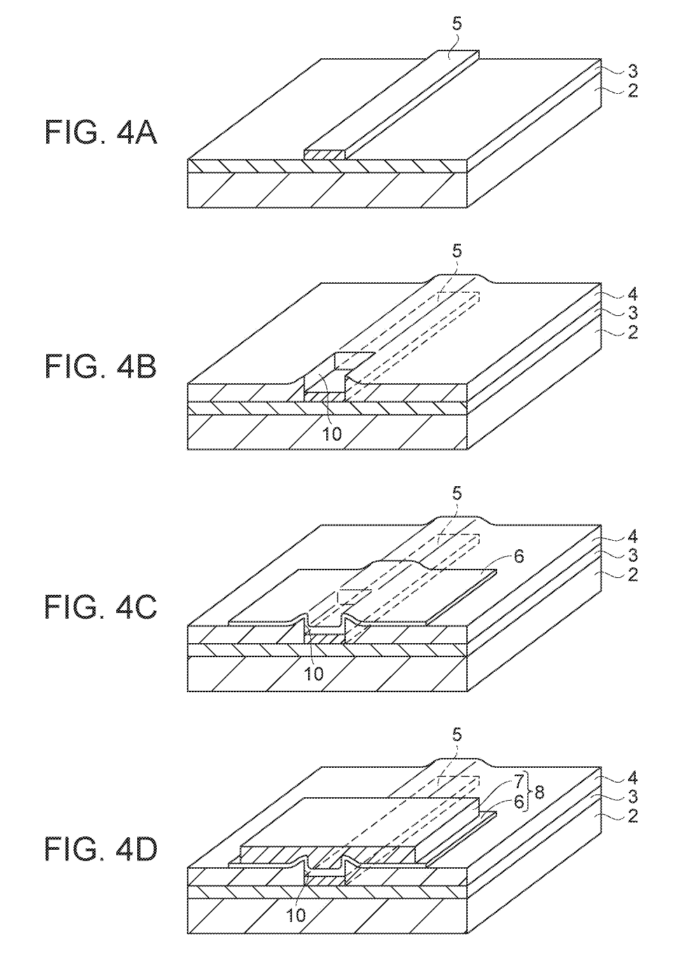

Next, with reference to FIG. 3 and FIG. 4, a method for manufacturing an integrated circuit will be described. FIG. 3 is a flowchart illustrating manufacture steps of an integrated circuit. FIG. 4 is a partially broken perspective view illustrating a process for manufacturing an integrated circuit.

First, as shown in FIG. 4A, there are formed, on the silicon substrate 2, a semiconductor element (not shown), the insulation layer 3, and the conductive wiring 5 (including an element electrode) by a known technique for manufacturing a semiconductor integrated circuit (step S1 of FIG. 3). For example, the conductive wiring 5 is formed by a pattern etching by the photolithography method after Al is formed on one surface of the insulation layer 3 by the sputter technique.

Next, as shown in FIG. 4B, the covering layer 4 for covering the conductive wiring 5 is formed (Step S2 of FIG. 3). Then, the contact hole 10 is formed in one region just above the conductive wiring 5 (Step S3 of FIG. 3).

Next, the surface of the covering layer 4 is subjected to a surface treatment

(Step S4 of FIG. 3). The surface treatment is a treatment in which, prior to the next step for arranging the liquid material (Ni dispersion) (Step S5 of FIG. 3), the surface of the covering layer 4 is treated in order to control the wetting property of the liquid material. Specifically, the surface treatment provides a processing for providing a lyophilic surface (e.g., O₂ plasma processing, ultraviolet light irradiation). Alternatively, a lyophilic region also may be patterned as required by a mask so that the shape of an expansion of wet liquid material can be suitably controlled.

Next, the Ni dispersion is patterned, by the droplet discharging apparatus 200 (see FIG. 2), on a region on the covering layer 4 including the contact hole 10 and is subjected to a drying processing, thereby forming the foundation layer 6 as shown in FIG. 4(c) (Step S5 of FIG. 3). Although the foundation layer 6 in FIG. 4 is shown to have a rectangular shape, the shape is not limited and also may be a circular shape.

The drying processing is a processing for drying and solidifying the Ni dispersion placed on the covering layer 4. For example, the drying processing can be performed by a heat processing by a hot plate, an electric furnace or the like, an optical processing by an infrared lamp or the like, or a decompression processing by a vacuum apparatus. These processes also can be performed in inert gas such as nitrogen. It is noted that conditions related to a drying rate (e.g., heating temperature, degree of vacuum) have a strong influence on the flatness of a film surface during the film formation and thus must be appropriately controlled. Thus, rapid drying should be avoided because it deteriorates the flatness. Furthermore, this drying processing does not require all liquid components to be removed and the liquid only have to be solidified to a level at which the Ni dispersion loses its flowability.

Next, the droplet discharging apparatus 200 (see FIG. 2) is used to pattern the Au dispersion on the foundation layer 6 to dry the Au dispersion, thereby forming the surface layer 7 as shown in FIG. 4(d) (Step S6 of FIG. 3). By repeating the placement of the Au dispersion and the drying processing a plurality of times, the surface layer 7 is formed to have a thickness thicker than that of the foundation layer 6.

Next, liquid components and coating agent left on the foundation layer 6 and the surface layer 7 for example are volatilized by a firing by a hot plate or an electric furnace for example and the Ni particles and Au particles are sintered (Step S7 of FIG. 3). It is noted that the firing must be performed with a temperature that does not cause deterioration of the element characteristic.

Thereafter, the silicon substrate 2 is diced and the respective diced members are individually subjected to a wire bonding, a resin molding or the like (Step S8 of FIG. 3), thereby completing the integrated circuit 1 shown in FIG. 1.

As described above, the manufacture method of First Embodiment forms the foundation layer 6 and the surface layer 7 constituting the bonding pad 8 by the droplet discharging method, thus requiring manufacture steps fewer than those required by the photolithography technique. Furthermore, the use of the Ni dispersion and the Au dispersion well matched with the droplet discharging method for the formation of the foundation layer 6 and the surface layer 7 reduces the burdening factors to the droplet discharging-related steps.

### Second Embodiment

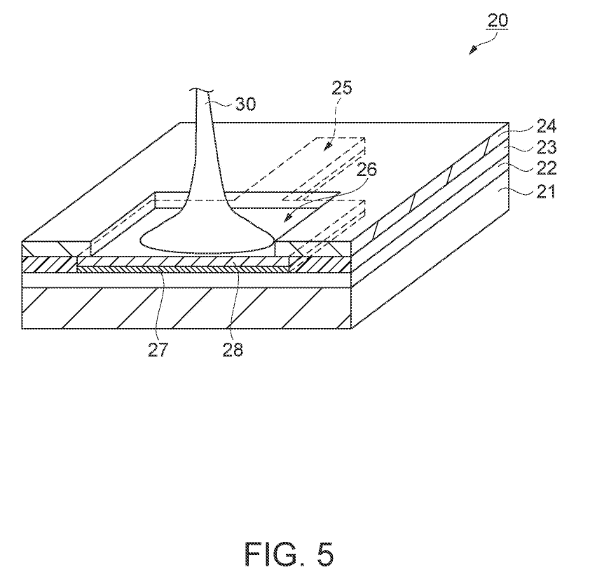

The following section will describe Second Embodiment of the invention with reference to FIG. 5 mainly with regards to the difference between Second Embodiment and First Embodiment. FIG. 5 is a partially broken perspective view illustrating the main structure of an electronic device of Second Embodiment.

In FIG. 5, an integrated circuit 20 as an electronic device includes: a silicon substrate 21 including a semiconductor element (not shown); an insulation layer 22 as an Si-base insulation layer formed on the silicon substrate 21; a bank layer 23; and a conductive wiring 25 and a bonding pad 26 integrally formed by the droplet discharging method. The bank layer 23 is made of photosensitive resin for example and is patterned by the photolithography technique so that regions in which the conductive wiring 25 and the bonding pad 26 are formed can be divided.

The conductive wiring 25 and the bonding pad 26 have a layered structure composed of an Ni-made foundation layer 27 and an Au-made surface layer 28 that are formed by the droplet discharging method, respectively. Specifically, the foundation layer 27 and the surface layer 28 are respectively formed by placing liquid material (Ni dispersion and Au dispersion) within the divided regions of the bank layer 23 by the droplet discharging method to subsequently subject the foundation layer 27 and the surface layer 28 to a drying processing. In this manner, the use of the bank layer 23 can allow the droplet discharging method to provide a thin film patterned with an accuracy comparable to that of the photolithography technique.

Alternatively, prior to the placement of the liquid material, the surface of the insulation layer 22 within the divided region also may be caused to be the lyophilic one by a lyophilic processing (e.g., O₂ plasma processing) or the surface of a bank layer 23 also may be caused to be the liquid-repellent one by a the liquid-repellent processing (e.g., CF₄ plasma processing). The preprocessing as described above can further improve the accuracy of the above-described patterning.

The integrated circuit 20 also includes a covering layer 24 that covers the bank layer 23 and the conductive wiring 25 and that is made of SiO₂, SiN or the like. The covering layer 24 is formed by layering insulation material on the entire top surface of the bank layer 23, the conductive wiring 25, and the bonding pad 26 to selectively etch a region corresponding to the bonding pad 26. Then, an exposed surface of the bonding pad 26 (surface layer 28) is joined with the bonding wire 30.

As in this embodiment, the bonding pad according to the invention can be integrally formed with a conductive wiring. Alternatively, the bonding pad also can be patterned by the droplet discharging method by a physical dividing means like a bank layer.

The invention is not limited to the above-described embodiment.

For example, an electronic device to which the invention is applied includes, in addition to the above-described integrated circuit, various semiconductor devices such as an acceleration sensor, a gyro sensor, or a laser device.

Alternatively, the foundation layer also can be formed by liquid material that includes, instead of Ni or in addition to Ni, Cr and Mn and a compound (oxide in particular) thereof. When the foundation layer functions as an electrical connection between the conductive wiring and the surface layer as in First Embodiment however, the use of Mn having a high electric resistance or liquid material including oxide is not preferred.

Furthermore, the surface layer also can be formed by liquid material that includes, instead of Au or in addition to Au, Ag and Cu or a compound thereof.

Furthermore, the bonding pad according to the invention also can be formed on an Si layer (Si surface layer of a substrate).

Furthermore, the placement of the liquid material by the droplet discharging method also can be performed by a dispenser for example.

Each of the structures of the respective embodiments also can be appropriately combined with each other, omitted, or combined with another structure not shown herein.

What is claimed is:

1. A method for manufacturing an electronic device in which a bonding pad composed of a foundation layer and a surface layer is formed on an Si layer or an Si-base insulation layer, comprising:
forming, on the Si layer or Si-base insulation layer and by a droplet discharging method, the foundation layer using liquid material including one or more material(s) selected from Ni, Cr, and Mn or a compound thereof; and
forming, on the foundation layer and by the droplet discharging method, the surface layer.

2. The method for manufacturing an electronic device according to claim 1, wherein the surface layer is formed by liquid material including one or more particle(s) or a compound material selected from Au, Ag, and Cu.

3. An electronic device in which a bonding pad composed of a foundation layer and a surface layer is formed on an Si layer or an Si-base insulation layer, wherein:
the foundation layer is formed on the Si layer or Si-base insulation layer by the droplet discharging method using liquid material including one or more material(s) selected from Ni, Cr, and Mn or a compound thereof; and
the surface layer is formed on the foundation layer by the droplet discharging method.
